(19) United States
(12) Patent Application Publication
(10) Pub. No.: US 2017/0098666 A1
(43) Pub. Date: Apr. 6, 2017

(54) THIN FILM TRANSISTOR SUBSTRATE, DISPLAY APPARATUS INCLUDING THIN FILM TRANSISTOR SUBSTRATE, METHOD OF MANUFACTURING THIN FILM TRANSISTOR SUBSTRATE, AND METHOD OF MANUFACTURING DISPLAY APPARATUS

(71) Applicant: Samsung Display Co., Ltd., Yongin-City (KR)

(72) Inventor: Junghyun Kim, Yongin-City (KR)

(21) Appl. No.: 15/176,510

(22) Filed: Jun. 8, 2016

(30) Foreign Application Priority Data
Oct. 5, 2015 (KR) 10-2015-0139994

(51) Int. Cl. H01L 27/12; H01L 29/66; H01L 51/05; H01L 27/28; H01L 29/786

(52) U.S. Cl. CPC H01L 27/1222; H01L 27/283; H01L 29/78669; H01L 29/78678; H01L 51/0545; H01L 29/66765; H01L 27/1259; H01L 27/3262

(57) ABSTRACT

A thin film transistor (TFT) substrate in which properties of a TFT may be modified according to a function of the TFT, a display apparatus including the TFT substrate, a method of manufacturing the TFT substrate, and a method of manufacturing the display apparatus. The thin film transistor (TFT) substrate includes a substrate; a first TFT disposed on the substrate and comprising a first active pattern and a first gate electrode at least partially overlapping with the first active pattern and disposed between the substrate and the first active pattern; and a second TFT disposed on the substrate and comprising a second active pattern and a second gate electrode at least partially overlapping with the second active pattern.

### RELATED APPLICATION

This application claims the priority to and all the benefits accruing under 35 U.S.C. §119 of Korean Patent Application No. 10-2015-0139994, filed on 5 Oct. 2015 in the Korean Intellectual Property Office (KIPO), the disclosure of which is incorporated herein in its entirety by reference.

### BACKGROUND

1. Field of Disclosure

One or more exemplary embodiments relate to a thin film transistor (TFT) substrate, a display apparatus including the TFT substrate, a method of manufacturing the TFT substrate, and a method of manufacturing the display apparatus, and more particularly, to a TFT substrate in which properties of a TFT may be modified according to a function of the TFT, a display apparatus including the TFT substrate, a method of manufacturing the TFT substrate, and a method of manufacturing the display apparatus.

2. Description of the Related Art

In general, a thin film transistor (TFT) substrate refers to a structure in which at least one TFT is formed on a substrate. A display apparatus may be manufactured by using the TFT substrate.

A TFT in the TFT substrate has an active layer that includes a crystalline silicon layer. The crystalline silicon layer is formed by crystallizing an amorphous silicon layer, and properties of the TFT are determined according to the crystallizing method. Different ranges of the properties of the TFT are required according to a function of the TFT in a circuit.

### SUMMARY OF THE INVENTION

In a thin film substrate (TFT) substrate of the related art, it may not be convenient to modify properties of a TFT according to a function of the TFT in a circuit in which a plurality of TFTs are present. In a display apparatus including such a TFT substrate, images may be displayed with different brightness intensities even when identical electric signals are applied to a plurality of pixels.

One or more exemplary embodiments include a TFT substrate in which properties of a TFT such as mobility may be modified, a display apparatus including the TFT substrate, a method of manufacturing the TFT substrate, and a method of manufacturing the display apparatus. However, the exemplary embodiments are not limited thereto.

Additional aspects will be set forth in part in the description which follows and, in part, will be apparent from the description, or may be learned by practice of the presented embodiments.

According to one or more exemplary embodiments, a thin film transistor (TFT) substrate includes a substrate; a first TFT disposed on the substrate and including a first active pattern and a first gate electrode at least partially overlapping with the first active pattern and disposed between the substrate and the first active pattern; and a second TFT disposed on the substrate and including a second active pattern and a second gate electrode at least partially overlapping with the second active pattern.

A first insulating layer may be disposed between the first gate electrode and the first active pattern.

The first active pattern and the second active pattern may be disposed on the same layer and the first gate electrode and the second gate electrode are disposed on different layers.

The first active pattern and the second active pattern may be disposed on the first insulating layer.

A second insulating layer may be disposed between the second active pattern and the second gate electrode.

The second gate electrode may be disposed on the second insulating layer.

The second insulating layer may be disposed on the first insulating layer, the first insulating layer may ha a first thickness, the second insulating layer may have a second thickness, and the first thickness may be greater than the second thickness.

The TFT substrate may further include a third insulating layer disposed on the second insulating layer and covering the second gate electrode.

The second TFT may be synchronized with a scan signal and transfers a data signal, and the first TFT outputs a driving current in response to the data signal.

According to one or more exemplary embodiments, a display apparatus includes the TFT substrate; and a display device disposed on the TFT substrate.

According to one or more exemplary embodiments, a method of manufacturing a thin film transistor (TFT) substrate includes forming a first gate electrode on a substrate; forming a first active pattern on the first gate electrode such that the first active pattern at least partially overlaps with the first gate electrode; forming a second active pattern on the substrate; and forming a second gate electrode on the second active pattern such that the second gate electrode at least partially overlaps with the second active pattern.

The method may further include, between the forming of the first gate electrode and the forming of the first active pattern, forming a first insulating layer.

The forming of the first active pattern and the forming of the second active pattern may be simultaneously performed, and the forming of the first gate electrode and the forming of the second gate electrode may be performed in different processes.

The first active pattern and the second active pattern may be formed on the first insulating layer.

The method may further include, between the forming of the second active pattern and the forming of the second gate electrode, forming a second insulating layer.

The second gate electrode may be formed on the second insulating layer.

The second insulating layer may be formed on the first insulating layer, and the first insulating layer may be formed to be thicker than the second insulating layer.

The method may further include forming a third insulating layer that covers the second gate electrode on the second insulating layer.

The second TFT may be synchronized with a scan signal and may transfer a data signal, and the first TFT may output a driving current in response to the data signal.

According to one or more exemplary embodiments, a method of manufacturing a display apparatus includes preparing a thin film transistor (TFT) substrate manufactured according to the method; and forming a display device on the TFT substrate.

These general and particular aspects may be carried out using a system, a method, a computer program, or a combination thereof.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a cross-sectional view schematically illustrating a thin film transistor (TFT) substrate according to an exemplary embodiment;

FIG. 2 is a cross-sectional view schematically illustrating a display apparatus according to an exemplary embodiment; and

FIGS. 3 through 8 are cross-sectional views schematically illustrating a method of manufacturing the TFT substrate of FIG. 1.

### DETAILED DESCRIPTION

As the inventive concept allows for various changes and numerous embodiments, particular embodiments will be illustrated in the drawings and described in detail in the written description. The effect and features of the inventive concept and the method of realizing the effect and the features will be clear with reference to the exemplary embodiments described in detail below with reference to the drawings. However, the inventive concept may be embodied in various forms and should not be construed as being limited to the exemplary embodiments. As used herein, the term “and/or” includes any and all combinations of one or more of the associated listed items. Expressions such as “at least one of,” when preceding a list of elements, modify the entire list of elements and do not modify the individual elements of the list.

The exemplary embodiments of the present inventive concept will be described in detail with reference to the accompanying drawings. Like reference numerals in the drawings denote like elements, and thus their description will not be repeated.

It will be understood that although the terms “first,” “second,” etc. may be used herein to describe various components, these components should not be limited by these terms. These components are only used to distinguish one component from another. As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components. It will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

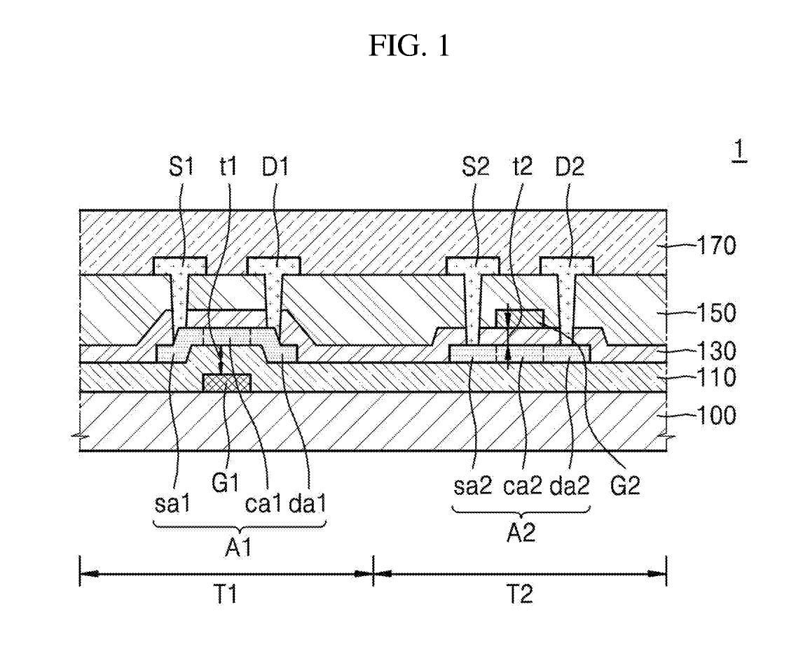

FIG. 1 is a cross-sectional view schematically illustrating a thin film transistor (TFT) substrate 1 according to an exemplary embodiment.

Referring to FIG. 1, the TFT substrate 1 according to an exemplary embodiment may include a substrate 100, a first TFT T1 disposed on the substrate 100 and including a first active pattern A1 and a first gate electrode G1, and a second TFT T2 disposed on the substrate 100 and including a second active pattern A2 and a second gate electrode G2.

The substrate 100 may include various materials, for example, a glass material, a metallic material, or a plastic material such as polyethylene terephthalate (PET), polyethylene naphthalate (PEN), and polyimide. The substrate 100 may include a display area in which a plurality of pixels (not shown) for displaying an image are disposed and a peripheral area that surrounds the display area.

At least one pixel, which displays an image, may be provided on the substrate 100. When there are a plurality of pixels, the pixels may be arranged in a matrix form. The pixels may emit red, green, yellow, and white and may have different areas. For example, the pixels with different colors may have different sizes or shapes according to a color of each pixel.

The pixel may include a wiring portion (not shown) that includes a gate line, a data line, and a driving voltage line, the first and second TFTs T1 and T2 connected to the wiring portion, and an organic light-emitting device (OLED).

The gate line may extend in one direction, and the data line may extend in another direction that intersects the gate line. The driving voltage line may extend in substantially the same direction as the data line. The gate line may transmit a scan signal to the first TFT T1, the data line may transmit a data signal to the first TFT T1, and the driving voltage line may supply a driving voltage to the first TFT T1. The second TFT T2 may receive the data signal from the data line, may be synchronized with the scan signal, and transfer the data signal to the first TFT T1, and the first TFT T1 may output a driving current in response to the data signal.

In the present embodiment, the first TFT T1 and the second TFT T2 may be provided on the substrate 100. As described above, the first TFT T1 may be a driving TFT, and the second TFT T2 may be a switching TFT. The first TFT T1 may include the first active pattern A1 and the first gate electrode G1 that at least partially overlaps with the first active pattern A1. The second TFT T2 may include the second active pattern A2 and the second gate electrode G2 that at least partially overlaps with the second active pattern A2.

The first gate electrode G1 may be provided on the substrate 100. The first gate electrode G1 is directly provided on the substrate 100 in FIG. 1 but the exemplary embodiments are not limited thereto. A barrier layer such as a buffer layer (not shown) may be provided on the substrate 100, and the first gate electrode G1 may be provided on the barrier layer. The first gate electrode G1 may include a single layer or multiple layers including at least one material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), by taking into account adhesion with adjacent layers, surface planarization of stacked layers, and processibility.

The first active pattern A1 that at least partially overlaps with the first gate electrode G1 may be provided on the first gate electrode G1. The first active pattern A1 may include a semiconductor material and include, for example, amorphous silicon, polycrystalline silicon, or an organic semiconductor material. The first active pattern A1 may function as an active layer of the first TFT T1. The first active pattern A1 may include a source area sa1, a drain area da1, and a channel area ca1 provided between the source and drain areas sa1 and da1. The source and drain areas sa1 and da1 of the first active pattern A1 may be doped with n-type or p-type impurities.

In this regard, in order to secure insulation between the first gate electrode G1 and the first active pattern A1, a first insulating layer 110 may be disposed between the first gate electrode G1 and the first active pattern A1. The first insulating layer 110 may be a buffer layer or a gate insulating layer. The first insulating layer 110 may include a single layer or multiple layers including a material such as silicon oxide or silicon nitride, etc. The first active pattern A1 may be provided on the first insulating layer 110.

A second insulating layer 130 may be provided on the first active pattern A1 and cover the first active pattern A1. The second insulating layer 130 may be provided on the first insulating layer 110. The second insulating layer 130 may be provided to secure insulation between the second active pattern A2 and the second gate electrode G2 of the second TFT T2, which will be described later. Another third insulating layer 150 may be provided on the second insulating layer 130. The second insulating layer 130 and the third insulating layer 150 may be gate insulating layers and interlayer insulating layers. The second insulating layer 130 and the third insulating layer 150 may each include a single layer or multiple layers including, for example, a material such as silicon oxide or silicon nitride, etc.

As shown in FIG. 1, the first insulating layer 110, the second insulating layer 130, and the third insulating layer 150 may be provided on the entire surface of the substrate 100.

The first TFT T1 may include a first source electrode S1 and a first drain electrode D1 that are electrically connected to the first active pattern A1 through contact holes formed in the second insulating layer 130 and the third insulating layer 150. The contact holes may both pass through the second insulating layer 130 and the third insulating layer 150 and may expose a part of the source and drain areas sa1 and da1 of the first active pattern A1. Through the contact holes formed in the second insulating layer 130 and the third insulating layer 150, the first source electrode S1 may be electrically connected to the source area sa1 of the first active pattern A1, and the first drain electrode D1 may be electrically connected to the drain area da1 of the first active pattern A1.

The first source electrode S1 and the first drain electrode D1 may include a single layer or multiple layers including at least one material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), by taking into account conductivity.

In other words, the first TFT T1 may be a bottom gate-type TFT in which the first gate electrode G1 is provided on the substrate 100, and the first active pattern A1 is provided on the first gate electrode G1. The first insulating layer 110 may be disposed between the first gate electrode G1 and the first active pattern A1 and may act as a gate insulating layer. The second insulating layer 130 and the third insulating layer 150 may be disposed between the first active pattern A1 and the first source electrode S1 and the first drain electrode D1 and may function as interlayer insulating layers.

The second active pattern A2 of the second TFT T2 may be provided on the substrate 100. In this regard, as shown in FIG. 1, the first insulating layer 110 may be disposed between the substrate 100 and the second active pattern A2. That is, the second active pattern A1 may be provided on the first insulating layer 110. In this case, the first insulating layer 110 may function as a buffer layer that prevents impurities from permeating into the second active pattern A2. The first insulating layer 110 may include a single layer or multiple layers including, for example, a material such as silicon oxide or silicon nitride, etc.

The second active pattern A2 may include a semiconductor material and include, for example, amorphous silicon, polycrystalline silicon, or the organic semiconductor material. The second active pattern A2 may function as an active layer of the second TFT T2. The second active pattern A2 may include a source area sa2, a drain area da2, and a channel area ca2 provided between the source and drain areas sa2 and da2. The source and drain areas sa2 and da2 of the second active pattern A2 may be doped with n-type or p-type impurities.

The second gate electrode G2 that at least partially overlaps with the second active pattern A2 may be provided on the second active pattern A2. The second gate electrode G2 may include a single layer or multiple layers including at least one material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), by taking into account adhesion with adjacent layers, surface planarization of stacked layers, and processibility.

In this regard, the second insulating layer 130 may be disposed between the second gate electrode G2 and the second active pattern A2. In this case, the second insulating layer 130 may be a gate insulating layer that secures insulation between the second gate electrode G2 and the second active pattern A2. The second insulating layer 130 may include a single layer or multiple layers including, for example, a material such as silicon oxide or silicon nitride, etc.

The third insulating layer 150 may be provided on the second gate electrode G2 to cover the second gate electrode G2. The third insulating layer 150 may be provided to secure insulation between the second gate electrode G2, a second source electrode S2, and a second drain electrode D2 and may be understood as an interlayer insulating layer. The third insulating layer 150 may include a single layer or multiple layers including, for example, a material such as silicon oxide or silicon nitride, etc. and an organic material.

The second source electrode S2 and the second drain electrode D2 may be provided on the third insulating layer 150. That is, the second TFT T2 may include the second source electrode S2 and the second drain electrode D2 that are electrically connected to the second active pattern A2 through contact holes formed in the second insulating layer 130 and the third insulating layer 150. The contact holes may both pass through the second insulating layer 130 and the third insulating layer 150 and may expose a part of the source and drain areas sa2 and da2 of the second active pattern A2. Through the contact holes formed in the second insulating layer 130 and the third insulating layer 150, the second source electrode S2 may be electrically connected to the source area sa2 of the second active pattern A2, and the second drain electrode D2 may be electrically connected to the drain area da2 of the second active pattern A2.

The second source electrode S2 and the second drain electrode D2 may each include a single layer or multiple layers including at least one material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), by taking into account conductivity.

In other words, in the second TFT T2, the first insulating layer 110 that functions as a buffer layer may be provided on the substrate 100, and the second active pattern A2 may be provided on the first insulating layer 110. The second TFT T2 may be a top gate-type TFT in which the second gate electrode G2 that at least partially overlaps with the second active pattern A2 is provided on the second active pattern A2. The second insulating layer 130 that acts as a gate insulating layer may be disposed between the second gate electrode G2 and the second active pattern A2. The third insulating layer 150 that functions as an interlayer insulating layer that insulates the second gate electrode G2 and the second source electrode S2 and the second drain electrode D2 may be provided on the second gate electrode G2. Through the contact holes that pass through the second insulating layer 130 and the third insulating layer 150, the second source electrode S2 and the second drain electrode D2 may be electrically connected to the second active pattern A2.

The first insulating layer 110 may have a first thickness t1, and the second insulating layer 130 may have a second thickness t2. In this regard, the first thickness t1 of the first insulating layer 110 may mean an interval between the first gate electrode G1 and the first active pattern A1, and the second thickness t2 of the second insulating layer 130 may mean an interval between the second gate electrode G2 and the second active pattern A2.

In this case, the first thickness t1 of the first insulating layer 110 may be greater than the second thickness t2 of the second insulating layer 130. Since the first insulating layer 110 that acts as a gate insulating layer of the first TFT T1 has a greater thickness than that of the second insulating layer 130 that acts as a gate insulating layer of the second TFT T2, a driving range of the first TFT T1 may be increased and simultaneously, a switching property of the second TFT T2 may be sensitively maintained.

As described above, the first active pattern A1 and the second active pattern A2 may be provided on the first insulating layer 110, the first gate electrode G1 may be provided below the first active pattern A1, and the second gate electrode G2 may be provided on the second active pattern A2. That is, the first gate electrode G1 and the second gate electrode G2 may be positioned on different layers, thereby individually modifying properties of the first TFT T1 and the second TFT T2.

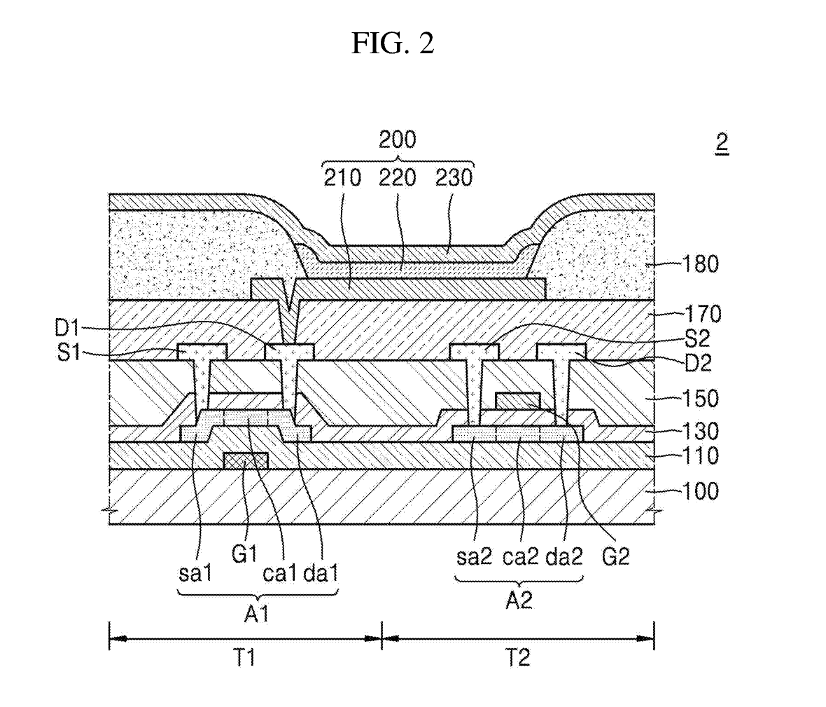

FIG. 2 is a cross-sectional view schematically illustrating a display apparatus 2 according to an exemplary embodiment.

Referring to FIG. 2, a display device may be further provided on the TFT substrate 1 of FIG. 1. The display device may be a liquid crystal device and may be an organic light-emitting device 200. A case where the organic light-emitting device 200 is provided on the TFT substrate 1 is described in the present embodiment.

A fourth insulating layer 170 may be provided on the first TFT T1 and the second TFT T2. In this case, the fourth insulating layer 170 may be a planarization layer or a protection layer. In a case where the organic light-emitting device is provided on a TFT, the fourth insulating layer 170 may planarize an upper surface of the TFT and protect the TFT and various devices. The fourth insulating layer 170 may include, for example, an acryl-based organic material or benzocyclobutene (BCB), etc. In this regard, as shown in FIG. 1, the fourth insulating layer 170 may be formed on the entire surface of the TFT substrate 1, like the first through third insulating layers 110, 130, and 150.

Although not shown, a protection layer (not shown) that covers the TFT may be provided in order to protect the TFT having the above-described structure. The protection layer may include, for example, an inorganic material such as silicon oxide, silicon nitride, or silicon oxynitride, etc.

A fifth insulating layer 180 may be provided on the fourth insulating layer 170 (FIG. 2). In this case, the fifth insulating layer 180 may be a pixel-defining layer. The fifth insulating layer 180 may be provided on the fourth insulating layer 170 and may have an opening. The fifth insulating layer 180 may act to define a pixel area on the substrate 100.

The fifth insulating layer 180 may include, for example, an organic insulating material. The organic insulating material may include acrylic polymer such as poly(methyl methacrylate) (PMMA), polystyrene (PS), a polymer derivative having a phenol group, imide polymer, acryl ester-based polymer, amide-based polymer, fluorine-based polymer, p-xylene polymer, vinyl alcohol polymer, and a mixture thereof.

The organic light-emitting device 200 may be disposed on the fourth insulating layer 170. The organic light-emitting device 200 may include a pixel electrode 210, an intermediate layer 220 including an emission layer EML (not shown), and an opposite electrode 230.

The pixel electrode 210 may be a (semi-)transparent electrode or a reflective electrode. When the pixel electrode 210 is a (semi-)transparent electrode, the pixel electrode 210 may include indium tin oxide (ITO), indium zinc oxide (IZO), zinc oxide (ZnO), indium oxide (In₂O₃), indium gallium oxide (IGO), or aluminum zinc oxide (AZO). When the pixel electrode 210 is a reflective electrode, the pixel electrode 210 may include a reflective layer having silver (Ag), magnesium (Mg), aluminum (Al), platinum (Pt), palladium (Pd), gold (Au), Nickel (Ni), Neodymium (Nd), Iridium (Ir), chromium (Cr), and a mixture thereof, and a layer including indium tin oxide (ITO), indium zinc oxide (IZO), zinc oxide (ZnO), indium oxide (In₂O₃), indium gallium oxide (IGO), or aluminum zinc oxide (AZO). The inventive concept is not limited thereto. The pixel electrode 210 may include various materials, and a structure thereof may be modified in various forms including a single layer or a multilayer.

The intermediate layer 220 may be disposed in the pixel area defined by the fifth insulating layer 180. The intermediate layer 220 may include an emission layer EML that emits light according to an electrical signal. In addition to the emission layer EML, the intermediate layer 220 may include a single or complex structure including a hole injection layer (HIL) disposed between the emission layer EML and the pixel electrode 210, a hole transport layer (HTL), and an electron transport layer (ETL) disposed between the emission layer EML and the opposite electrode 230, or an electron injection layer. However, the intermediate layer 220 is not limited thereto, and may have various structures.

The opposite electrode 230 may be disposed on the whole surface of the substrate 100 and cover the intermediate layer 220 including the emission layer EML and face the pixel electrode 210. The opposite electrode 230 may be a (semi-)transparent electrode or a reflective electrode.

When the opposite electrode 230 is a (semi-)transparent electrode, the opposite electrode 230 may include a layer including metal having a small work function such as lithium (Li), calcium (Ca), lithium fluoride calcium (LiF/Ca), lithium fluoride aluminum (LiF/Al), aluminum (Al), silver (Ag), magnesium (Mg), or a mixture thereof, and a (semi-) transparent conductive layer of indium tin oxide (ITO), indium zinc oxide (IZO), zinc oxide (ZnO), or indium oxide (In₂O₃). When the opposite electrode 230 is a reflective electrode, the opposite electrode 230 may include a layer including lithium (Li), calcium (Ca), lithium fluoride calcium (LiF/Ca), lithium fluoride aluminum (LiF/Al), aluminum (Al), silver (Ag), magnesium (Mg), or a mixture thereof. However, the structure and materials of the opposite electrode 230 are not limited thereto, and may be modified in various forms.

The display apparatus 2 may include a plurality of pixels including the organic light-emitting device 200 that is a self-luminous device as described above. Each pixel may include a plurality of TFTs and a capacitor (not shown) for driving the organic light-emitting device 200. The plurality of TFTs may basically include a driving TFT and a switching TFT.

The switching TFT may include a gate insulating layer having a small thickness between a gate electrode and a semiconductor layer for a fast switching operation. In this regard, a thickness of a gate insulating layer of the driving TFT formed on the same layer as the switching TFT is also reduced, and thus a driving range of a gate voltage Vgs applied to a gate electrode of the driving TFT may be reduced. Therefore, it may be difficult to control the switching TFT to have a huge gradation by adjusting the magnitude of the gate voltage Vgs of the driving TFT. Although a method of increasing a length of an active pattern is preset in order to secure the driving range of the driving TFT, since this needs an additional area due to a structure, an increase in the length of the active pattern at a high resolution may be limited.

In other words, the driving range of a conventional driving TFT may be secured by increasing a thickness of the gate insulating layer. In this case, the driving range may be increased by increasing the thickness of the gate insulating layer and reducing an electric field applied to the gate electrode. However, such a structure increases the thickness of the gate insulating layer, which causes properties of the switching TFT formed simultaneously with the driving TFT to deteriorate.

The method of increasing the length of the active pattern may increase the driving range of the driving TFT by reducing a transfer property of a device. However, such a design results in a reduction in an area of a unit pixel at a high resolution, and thus it is impossible to use the method at a high resolution exceeding a certain level.

Therefore, the TFT substrate 1 and the display apparatus 2 including the TFT substrate 1 according to an exemplary embodiment provide a structure capable of securing the driving range of the driving TFT while not deteriorating properties of the switching TFT.

The TFT substrate 1 according to an exemplary embodiment may provide the first gate electrode G1 of the first TFT T1 corresponding to the driving TFT disposed below the first active pattern A1 and the first insulating layer 110 disposed between the first gate electrode G1 and the first active pattern A1, thereby modifying the driving range of the first TFT T1 by modifying a thickness of the first insulating layer 110. The TFT substrate 1 according to an exemplary embodiment may also provide the second gate electrode G2 of the second TFT T2 corresponding to the switching TFT disposed above the second active pattern A2 and the second insulating layer 130 disposed between the second gate electrode G2 and the second active pattern A2, thereby individually forming the first insulating layer 110 and the second insulating layer 130.

In the present embodiment, the properties of the first TFT T1 and the second TFT T2 may be modified by modifying individual thicknesses of the first insulating layer 110 and the second insulating layer 130. That is, the first insulating layer 110 may be formed to be relatively thicker than the second insulating layer 130, and thus the driving range of the first TFT T1 that uses the first insulating layer 110 as the gate insulating layer may be increased. The second insulating layer 130 may also be formed to be relatively thinner than the first insulating layer 110, and thus the second TFT T2 that uses the second insulating layer 130 as the gate insulating layer may perform a fast switching operation.

Accordingly, the properties of the first TFT T1 and the second TFT T2 may be individually modified. In the first TFT T1, the first gate electrode G1 is below the first active pattern A1, and thus an opening ratio may not additionally reduced, and the first TFT T1 may have a great driving range irrespective of the increase in the length of the first active pattern A1, thereby applying the first TFT T1 to a high resolution.

The TFT substrate 1 and the display apparatus 2 including the TFT substrate 1 are described above but the exemplary embodiments are not limited thereto. For example, a method of manufacturing the TFT substrate 1 and the display apparatus 2 including the TFT substrate 1 may also be within the scope of the exemplary embodiments.

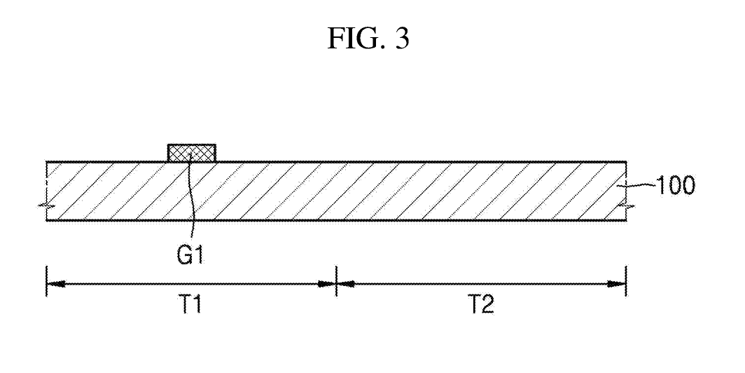

FIGS. 3 through 6 are cross-sectional views schematically illustrating a method of manufacturing the TFT substrate 1 of FIG. 1.

Referring to FIT. 3, an operation of forming the first gate electrode G1 of the first TFT T1 on the substrate 100 may be performed. The substrate 100 may include various materials, for example, a glass material, a metallic material, or a plastic material such as polyethylene terephthalate (PET), polyethylene naphthalate (PEN), and polyimide. The first gate electrode G1 is directly provided on the substrate 100 in FIG. 3 but the exemplary embodiments are not limited thereto. A barrier layer such as a buffer layer (not shown) may be provided on the substrate 100 as a single layer or multiple layers and the first gate electrode G1 may be formed on the barrier layer.

The first gate electrode G1 may include a single layer or multiple layers including at least one material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), by taking into account adhesion with adjacent layers, surface planarization of stacked layers, and processibility.

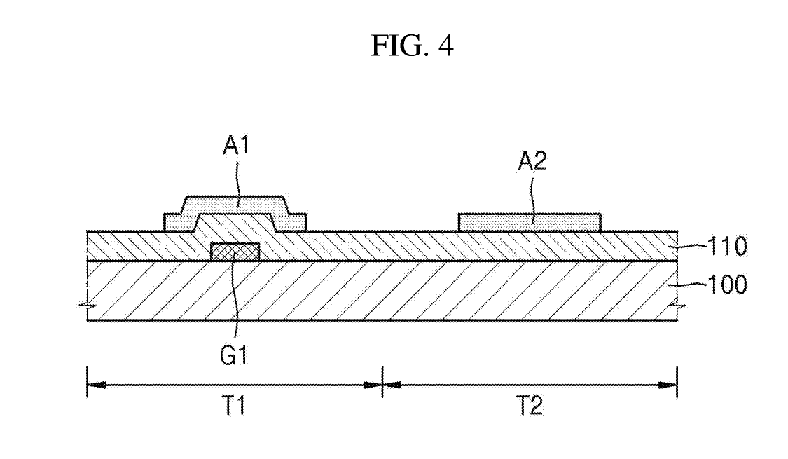

Thereafter, referring to FIG. 4, the first insulating layer 110 may be formed on the first gate electrode G1 to cover the first gate electrode G1. The first insulating layer 110 may include a single layer or multiple layers including a material such as silicon oxide or silicon nitride, etc. The first insulating layer 110 may be provided to secure insulation between the first active pattern A1 and the first gate electrode G1. The first insulating layer 110 may function as a gate insulating layer of the first TFT T1 and a buffer layer of the second TFT T2.

The first active pattern A1 of the first TFT T1 and the second active pattern A2 of the second TFT T2 may be formed on the first insulating layer 110. The first active pattern A1 and the second active pattern A2 may include a semiconductor material and include, for example, amorphous silicon, polycrystalline silicon, or an organic semiconductor material. The first active pattern A1 may function as an active layer of the first TFT T1. The second active pattern A2 may function as an active layer of the second TFT T2. The first active pattern A1 may include the source area sa1, the drain area da1, and the channel area ca1 provided between the source and drain areas sa1 and da1. The second active pattern A2 may include the source area sa2, the drain area da2, and the channel area ca2 provided between the source and drain areas sa2 and da2. The source areas sa1 and sa2 and the drain areas da1 and da2 of the first active pattern A1 and the second active pattern A2 may be doped with n-type or p-type impurities.

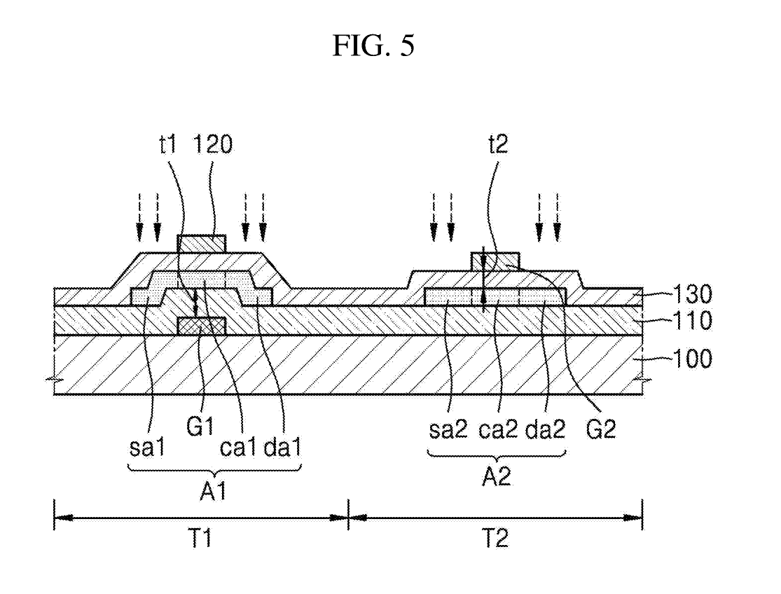

Thereafter, referring to FIG. 5, the second insulating layer 130 may be formed on the first active pattern A1 and the second active pattern A2 and cover the first active pattern A1 and the second active pattern A2. The second insulating layer 130 may include a single layer or multiple layers including, for example, a material such as silicon oxide or silicon nitride, etc.

The first insulating layer 110 may have the first thickness t1, and the second insulating layer 130 may have the second thickness t2. In this regard, the first thickness t1 of the first insulating layer 110 may mean an interval between the first gate electrode G1 and the first active pattern A1, and the second thickness t2 of the second insulating layer 130 may mean an interval between the second gate electrode G2 and the second active pattern A2.

In this case, the first thickness t1 of the first insulating layer 110 may be greater than the second thickness t2 of the second insulating layer 130. Since the first insulating layer 110 that acts as the gate insulating layer of the first TFT T1 has a greater thickness than that of the second insulating layer 130 that acts as the gate insulating layer of the second TFT T2, a driving range of the first TFT T1 may be increased and simultaneously, a switching property of the second TFT T2 may be sensitively maintained.

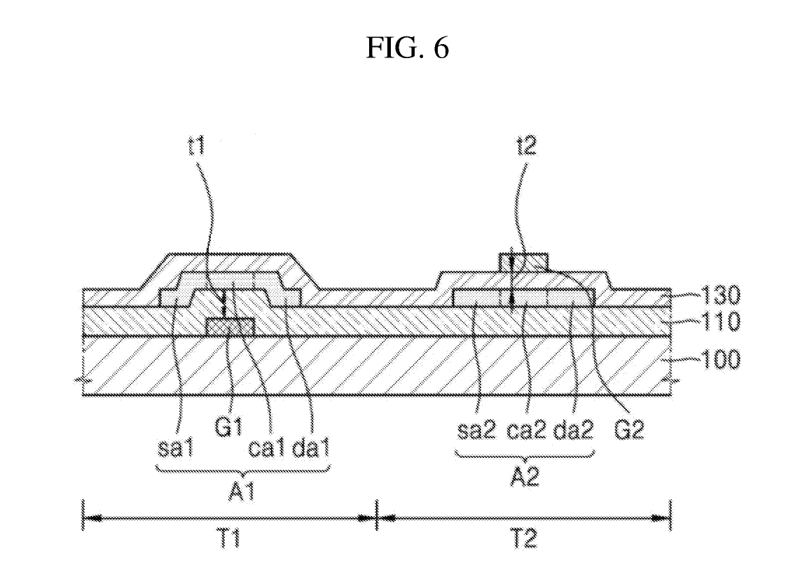

A dummy gate pattern 120 that at least partially overlaps with the first active pattern A1 may be formed on the second insulating layer 130. The dummy gate pattern 120 may correspond to the first gate electrode G1 formed in a lower portion of the first active pattern A1. The dummy gate pattern 120 may be used to dope the first active pattern A1 (FIG. 5) and may be removed after doping the first active pattern A1 as shown in FIG. 6.

The second gate electrode G2 that at least partially overlaps with the second active pattern A2 may be formed on the second insulating layer 130. The second gate electrode G2 may include a single layer or multiple layers including at least one material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), by taking into account adhesion with adjacent layers, surface planarization of stacked layers, and processibility.

After forming the dummy gate pattern 120 and the second gate electrode G2 on the second insulating layer 130, as shown in FIG. 5, an operation of doping the first active pattern A1 and the second active pattern A2 may be formed. Through the operation of doping the first active pattern A1 and the second active pattern A2 with n-type or p-type impurities, the source area sa1, the drain area da1, and the channel area ca1 provided between the source and drain areas sa1 and da1 may be formed in the first active pattern A1, and the source area sa2, the drain area da2, and the channel area ca2 provided between the source and drain areas sa2 and da2 may be formed in the second active pattern A2.

Thereafter, as described above, a dummy gate pattern 120 may be removed (FIG. 6).

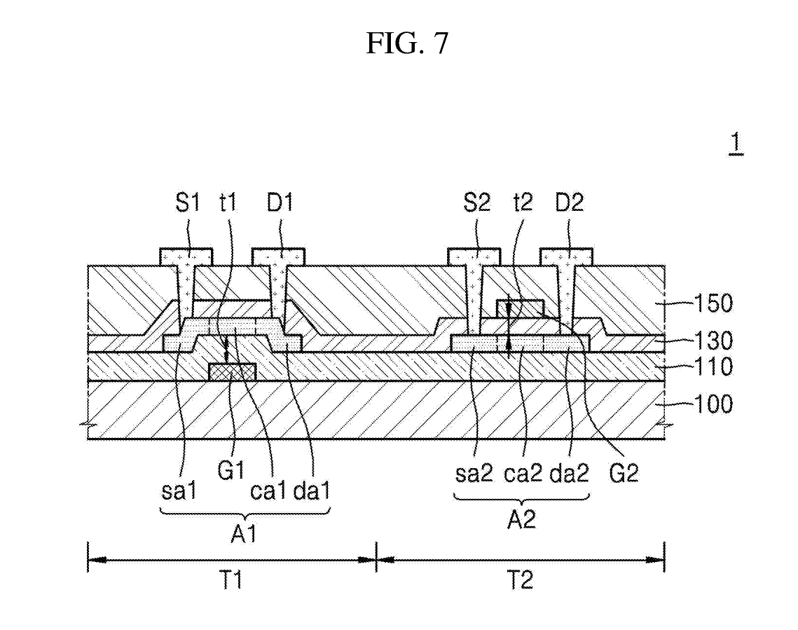

Thereafter, referring to FIG. 7, the third insulating layer 150 may be formed on the second insulating layer 130 to cover the second gate electrode G2. The third insulating layer 150 may include a single layer or multiple layers including, for example, a material such as silicon oxide or silicon nitride, etc. and an organic material. The third insulating layer 150 may function as an interlayer insulating layer of the first TFT T1 and the second TFT T2.

The first source electrode S1 and the first drain electrode D1 of the first TFT T1 may be formed on the third insulating layer 150. The second source electrode S2 and the second drain electrode D2 of the second TFT T2 may be formed on the third insulating layer 150. Through contact holes formed in the second insulating layer 130 and the third insulating layer 150, the first source electrode S1 may be electrically connected to the source area sa1 of the first active pattern A1, and the first drain electrode D1 may be electrically connected to the drain area da1 of the first active pattern A1. Through the contact holes formed in the second insulating layer 130 and the third insulating layer 150, the second source electrode S2 may be electrically connected to the source area sa2 of the second active pattern A2, and the second drain electrode D2 may be electrically connected to the drain area da2 of the second active pattern A2.

The first source electrode S1 and the first drain electrode D1 and the second source electrode S2 and the second drain electrode D2 may each include a single layer or multiple layers including at least one material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), by taking into account conductivity.

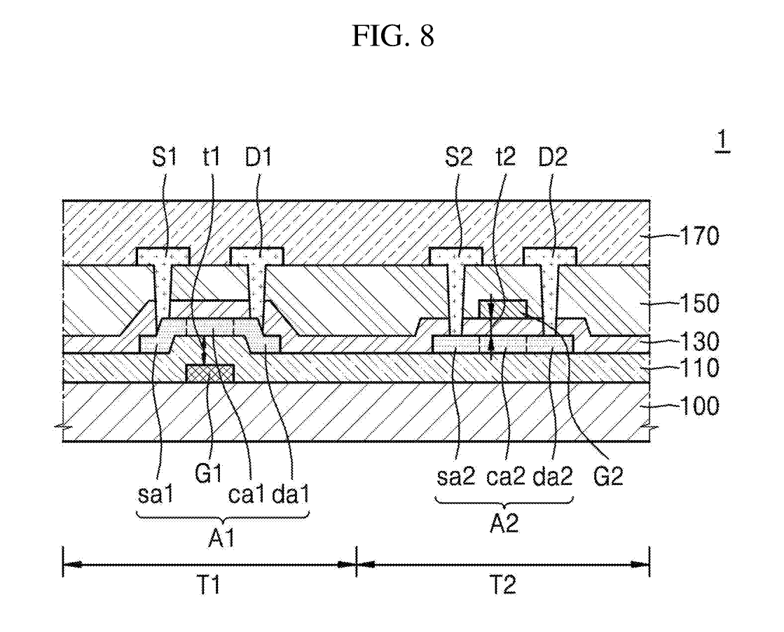

The fourth insulating layer 170 may be formed on the third insulating layer 150 to cover the first source electrode S1 and the first drain electrode D1 and the second source electrode S2 and the second drain electrode D2 (FIG. 8). Light-emitting devices may be formed on the fourth insulating layer 170, and thus the fourth insulating layer 170 may function as a planarization layer. The above-described first through fourth insulating layer 110 through 170 may be formed on the entire surface of the substrate 100.

Thereafter, referring to FIG. 2, a via hole for electrically connecting the first drain electrode D1 of the first TFT T1 and the pixel electrode 210 may be formed in the fourth insulating layer 170. Through the via hole, the pixel electrode 210 and the first TFT T1 may be electrically connected.

The pixel electrode 210 may be formed on the first insulating layer 10. The pixel electrode 210 may be pattered for each pixel. After forming the pixel electrode 210, the fifth insulating layer 180 may be formed to cover an edge of the pixel electrode 21 and expose a center portion thereof. In this case, the fifth insulating layer 180 may be a pixel-defining layer. The fifth insulating layer 180 may be formed on the fourth insulating layer 170 and may have an opening. The fifth insulating layer 180 may act to define a pixel area on the substrate 100.

The fourth insulating layer 170 and the fifth insulating layer 180 may include, for example, an organic insulating material. The organic insulating material may include acrylic polymer such as poly(methyl methacrylate) (PMMA), polystyrene (PS), a polymer derivative having a phenol group, imide polymer, acryl ester-based polymer, amide-based polymer, fluorine-based polymer, p-xylene polymer, vinyl alcohol polymer, and a mixture thereof.

The organic light-emitting device 200 may be disposed on the fourth insulating layer 170. The organic light-emitting device 200 may include the pixel electrode 210, the intermediate layer 220 including the emission layer EML, and the opposite electrode 230.

The display apparatus 2 may include a plurality of pixels including the organic light-emitting device 200 that is a self-luminous device as described above. Each pixel may include a plurality of TFTs and a capacitor (not shown) for driving the organic light-emitting device 200. The plurality of TFTs may basically include a driving TFT and a switching TFT.

The switching TFT may include a gate insulating layer having a small thickness between a gate electrode and a semiconductor layer for a fast switching operation. In this regard, a thickness of a gate insulating layer of the driving TFT formed on the same layer as the switching TFT is also reduced, and thus a driving range of a gate voltage Vgs applied to a gate electrode of the driving TFT may be reduced. Therefore, it may be difficult to control the switching TFT to have a huge gradation by adjusting the magnitude of the gate voltage Vgs of the driving TFT. Although a method of increasing a length of an active pattern is preset in order to secure the driving range of the driving TFT, since this needs an additional area due to a structure, an increase in the length of the active pattern at a high resolution may be limited.

In other words, the driving range of the conventional driving TFT may be secured by increasing a thickness of the gate insulating layer. In this case, the driving range may be increased by increasing the thickness of the gate insulating layer and reducing an electric field applied to the gate electrode. However, such a structure increases the thickness of the gate insulating layer, which causes properties of the switching TFT formed simultaneously with the driving TFT to deteriorate.

The method of increasing the length of the active pattern may increase the driving range of the driving TFT by reducing a transfer property of a device. However, such a design results in a reduction in an area of a unit pixel at a high resolution, and thus it is impossible to use the method at a high resolution exceeding a certain level.

Therefore, the TFT substrate 1 and the display apparatus 2 including the TFT substrate 1 according to an exemplary embodiment provide a structure capable of securing the driving range of the driving TFT while not deteriorating properties of the switching TFT.

The TFT substrate 1 according to an exemplary embodiment may provide the first gate electrode G1 of the first TFT T1 corresponding to the driving TFT disposed below the first active pattern A1 and the first insulating layer 110 disposed between the first gate electrode G1 and the first active pattern A1, thereby modifying the driving range of the first TFT T1 by modifying a thickness of the first insulating layer 110. The TFT substrate 1 according to an exemplary embodiment may also provide the second gate electrode G2 of the second TFT T2 corresponding to the switching TFT disposed above the second active pattern A2 and the second insulating layer 130 disposed between the second gate electrode G2 and the second active pattern A2, thereby individually forming the first insulating layer 110 and the second insulating layer 130.

In the present embodiment, the properties of the first TFT T1 and the second TFT T2 may be modified by modifying individual thicknesses of the first insulating layer 110 and the second insulating layer 130. That is, the first insulating layer 110 may be formed to be relatively thicker than the second insulating layer 130, and thus the driving range of the first TFT T1 that uses the first insulating layer 110 as the gate insulating layer may be increased. The second insulating layer 130 may also be formed to be relatively thinner than the first insulating layer 110, and thus the second TFT T2 that uses the second insulating layer 130 as the gate insulating layer may perform a fast switching operation.

Accordingly, the properties of the first TFT T1 and the second TFT T2 may be individually modified. In the first TFT T1, the first gate electrode G1 is below the first active pattern A1, and thus an opening ratio may not additionally reduced, and the first TFT T1 may have a great driving range irrespective of the increase in the length of the first active pattern A1, thereby applying the first TFT T1 to a high resolution.

As described above, according to the one or more of the above exemplary embodiments, a TFT substrate in which properties of a TFT may be adjusted according to a function of the TFT, a display apparatus including the TFT substrate, a method of manufacturing the TFT substrate, and a method of manufacturing the display apparatus are provided. However, the scope of the exemplary embodiments is not limited by these effects.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims.

What is claimed is:

1. A thin film transistor (TFT) substrate comprising:
a substrate;
a first TFT disposed on the substrate and comprising a first active pattern and a first gate electrode at least partially overlapping with the first active pattern and disposed between the substrate and the first active pattern; and
a second TFT disposed on the substrate and comprising a second active pattern and a second gate electrode at least partially overlapping with the second active pattern.

2. The TFT substrate of claim 1, wherein a first insulating layer is disposed between the first gate electrode and the first active pattern.

3. The TFT substrate of claim 1, wherein the first active pattern and the second active pattern are disposed on the same layer and the first gate electrode and the second gate electrode are disposed on different layers.

4. The TFT substrate of claim 1, wherein the first active pattern and the second active pattern are disposed on the first insulating layer.

5. The TFT substrate of claim 1, wherein a second insulating layer is disposed between the second active pattern and the second gate electrode.

6. The TFT substrate of claim 1, wherein the second gate electrode is disposed on the second insulating layer.

7. The TFT substrate of claim 1, wherein the second insulating layer is disposed on the first insulating layer, the first insulating layer has a first thickness, the second insulating layer has a second thickness, and the first thickness is greater than the second thickness.

8. The TFT substrate of claim 1, further comprising a third insulating layer disposed on the second insulating layer and covering the second gate electrode.

9. The TFT substrate of claim 1, wherein the second TFT is synchronized with a scan signal and transfers a data signal, and the first TFT outputs a driving current in response to the data signal.

10. A display apparatus comprising:
the TFT substrate of any one of claim 1; and
a display device disposed on the TFT substrate.

11. A method of manufacturing a thin film transistor (TFT) substrate, the method comprising:
forming a first gate electrode on a substrate;
forming a first active pattern on the first gate electrode such that the first active pattern at least partially overlaps with the first gate electrode;
forming a second active pattern on the substrate; and
forming a second gate electrode on the second active pattern such that the second gate electrode at least partially overlaps with the second active pattern.

12. The method of claim 11, further comprising, between the forming of the first gate electrode and the forming of the first active pattern, forming a first insulating layer.

13. The method of claim 11, wherein the forming of the first active pattern and the forming of the second active pattern are simultaneously performed, and the forming of the first gate electrode and the forming of the second gate electrode are performed in different processes.

14. The method of claim 11, wherein the first active pattern and the second active pattern are formed on the first insulating layer.

15. The method of claim 11, further comprising, between the forming of the second active pattern and the forming of the second gate electrode, forming a second insulating layer.

16. The method of claim 11, wherein the second gate electrode is formed on the second insulating layer.

17. The method of claim 11, wherein the second insulating layer is formed on the first insulating layer, and the first insulating layer is formed to be thicker than the second insulating layer.

18. The method of claim 11, further comprising forming a third insulating layer that covers the second gate electrode on the second insulating layer.

19. The method of claim 11, wherein the second TFT is synchronized with a scan signal and transfers a data signal, and the first TFT outputs a driving current in response to the data signal.

20. A method of manufacturing a display apparatus, the method comprising:
preparing a thin film transistor (TFT) substrate manufactured according to the method of any one of claim 11; and
forming a display device on the TFT substrate.
